(19) United States
(12) Patent Application Publication
(10) Pub. No.: US 2024/0239988 A1
(43) Pub. Date: Jul. 18, 2024

(54) SEMICONDUCTOR ELEMENT ENCAPSULATION RESIN COMPOSITION AND SEMICONDUCTOR DEVICE HAVING CURED PRODUCT THEREOF

(71) Applicant: Shin-Etsu Chemical Co., Ltd., Tokyo (JP)

(72) Inventor: Hiroki HORIGOME, Annaka-shi (JP)

(73) Assignee: Shin-Etsu Chemical Co., Ltd., Tokyo (JP)

(21) Appl. No.: 18/408,733

(22) Filed: Jan. 10, 2024

(30) Foreign Application Priority Data
Jan. 11, 2023 (JP) 2023-002147

(51) Int. Cl. C08K 3/22; C08G 73/10; C08K 3/36; H01L 23/29

(52) U.S. Cl. CPC C08K 3/22; C08G 73/10; C08K 3/36; H01L 23/295; C08K 2003/2206; C08K 2003/2227; C08K 2003/2237

(57) ABSTRACT

Provided is an encapsulation resin composition that is suitable for encapsulating a semiconductor element-mounted surface of a substrate with a semiconductor element(s) mounted thereon or a semiconductor element-forming surface of a wafer with a semiconductor element(s) formed thereon, is superior in low warpage property, and has a high relative permittivity and a low dielectric tangent. The encapsulation resin composition of the present invention contains:
(A) a maleimide compound having at least one dimer acid frame-derived hydrocarbon group per molecule;
(B) a reaction initiator;
(C) a high-relative permittivity inorganic filler having a relative permittivity of not lower than 10 at 1 MHz, the inorganic filler (C) being an inorganic filler other than the following component (D); and
(D) silica particles and/or alumina particles.

### BACKGROUND OF THE INVENTION

### Field of the Invention

The present invention relates to a resin composition suitable for encapsulating a semiconductor element-mounted surface of a substrate with a semiconductor element(s) mounted thereon or a semiconductor element-forming surface of a wafer with a semiconductor element(s) formed thereon: and a semiconductor device having a cured product of such resin composition.

### Background Art

In recent years, wafer level packaging and panel level packaging has gained attention as mobile devices such as smartphones have become smaller, lighter and more sophisticated. In wafer level packaging, a heat-curable resin is used to encapsulate a semiconductor element-mounted surface of an 8-inch or 12-inch substrate with a semiconductor element(s) mounted thereon or a semiconductor element-forming surface of a wafer with a semiconductor element(s) formed thereon, after which grinding, redistribution layer formation, solder ball mounting and so on are carried out before performing dicing so as to complete packaging. Techniques such as TSV (Through Silicon Via) and CoC (Chip on Chip) allow multiple layers of semiconductor elements to be connected with one another and mounted on a substrate such as a silicon interposer, whereby there can be produced a package with not only a reduced size and a reduced weight, but also a higher density. Further, unlike the conventional method where packaging is carried out after dicing a processed wafer into individual chips, there is also a merit of reducing production cost as packaging is carried out while in the state of a wafer, and the packaged wafer was then diced into individual chips as completed products.

Wafer level packaging and panel level packaging bears a problem of exhibiting warpages after encapsulation. While molding and encapsulation can be realized without any major problems if the substrate used is a small-diameter wafer or the like, a noticeable warpage will occur in the substrate if it is a 12-inch wafer as a wafer having a diameter of not smaller than 8 inches, or if performing panel level molding with an even larger area, due to a difference in thermal expansion coefficient between the substrate and a heat-curable resin. This warpage shall be problematic in later steps such as a transporting step, a grinding step, a probing step, and a dicing step, and may even modify an element characteristic(s) according to a device.

Further, in recent years, promoted is the development of an antenna-in-package (AiP) with antennas and a RF-IC being integrated into one package. Since antenna-in-packages are manufactured in bulk at the wafer level, they are required to exhibit a lower degree of warpage after encapsulation. Moreover, since antenna-in-packages can be made smaller, while materials used in antenna-in-packages are required to possess a high relative permittivity, they are also required to possess a low dielectric tangent in order to suppress transmission loss. As a material used in an antenna-in-package, there are known, for example, compositions obtained by adding a high-relative permittivity inorganic filler to an epoxy resin, which are disclosed in Japanese Patent No.6870778 and WO2022/123792(Al). However, if using these compositions on a large-area substrate or wafer of 12 inches or larger, a noticeable degree of warpage will be observed, and further improvements need to be made in dielectric tangent.

### SUMMARY OF THE INVENTION

Thus, it is an object of the present invention to provide an encapsulation resin composition that yields a reduced and restricted warpage even when applied to an electronic part requiring a low warpage property, and has a high relative permittivity and a low dielectric tangent.

In order to solve the above problems, the inventors of the present invention diligently conducted a series of studies, and completed the invention by finding that the encapsulation resin composition shown below was able to achieve the aforementioned object.

Specifically, the present invention is to provide the following encapsulation resin composition and a semiconductor device having a cured product of such composition.

<1>

An encapsulation resin composition for encapsulating a semiconductor element-mounted surface of a substrate with one or more semiconductor elements mounted thereon or a semiconductor element-forming surface of a wafer with one or more semiconductor elements formed thereon, comprising:
(A) a maleimide compound having at least one dimer acid frame-derived hydrocarbon group per molecule;
(B) a reaction initiator;
(C) a high-relative permittivity inorganic filler having a relative permittivity of not lower than 10 at 1 MHZ, the inorganic filler (C) being an inorganic filler other than the following component (D); and
(D) silica particles and/or alumina particles.
   <2>

The encapsulation resin composition according to <1>, wherein the component (A) is a maleimide compound represented by the following formula (1)

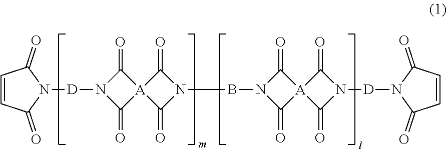

wherein A independently represents a tetravalent organic group having a cyclic structure; B independently represents a divalent hydrocarbon group that is not derived from a dimer acid frame and has 6 to 60 carbon atoms; D independently represents a divalent hydrocarbon group having 6 to 200 carbon atoms, in which at least one D represents a dimer acid frame-derived hydrocarbon group; m is 0 to 100, 1 is 0 to 200; no restrictions are imposed on an order of each repeating unit identified by m and 1, and a bonding pattern may be alternate, block or random.
<3>

The encapsulation resin composition according to <2>, wherein A in the formula (1) is any one of the tetravalent organic groups represented by the following structural formulae

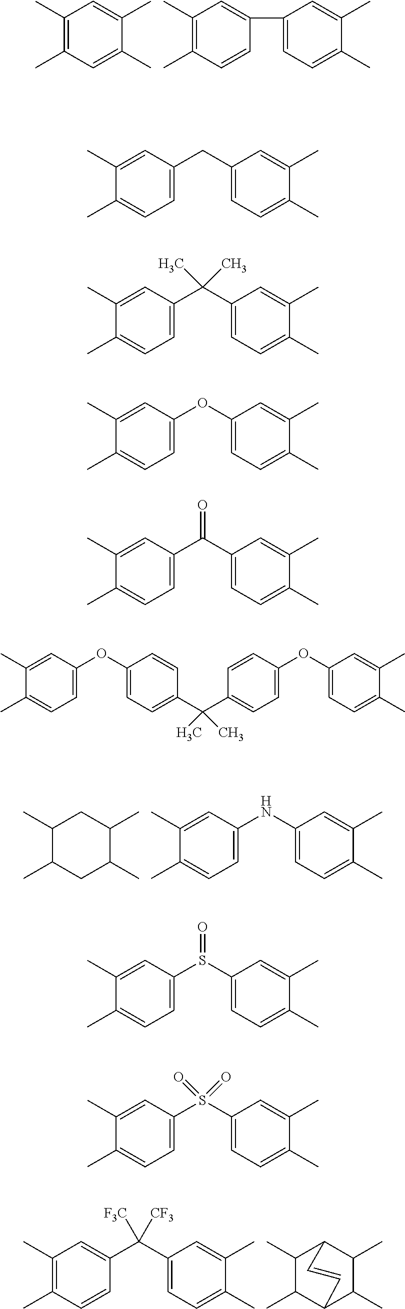

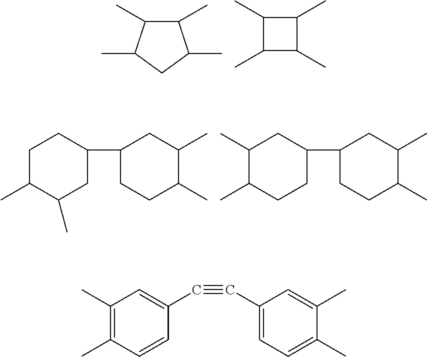

wherein bonds that are yet unbonded to substituent groups are to be bonded to carbonyl carbons forming cyclic imide structures in the formula (1).
<4>

The encapsulation resin composition according to <1>, wherein the component (C) is at least one kind selected from the group consisting of barium titanate, calcium titanate, strontium titanate, magnesium titanate, lead titanate, calcium zirconate, strontium zirconate, lanthanum oxide, and titanium oxide.

<5>

The encapsulation resin composition according to <1>, wherein the component (C) is contained in an amount of 5 to 90% by mass with respect to the whole composition, the component (D) is contained in an amount of 5 to 50% by mass with respect to the whole composition, and a sum total of the components (C) and (D) is in an amount of 10 to 95% by mass with respect to the whole composition.

<6>

The encapsulation resin composition according to <1>, wherein the component (B) is a thermal radical polymerization initiator and/or an anionic polymerization initiator.

<7>

The encapsulation resin composition according to <1>, wherein the encapsulation resin composition is in the form of granules, a sheet or a film.

<8>

The encapsulation resin composition according to <1>, wherein the encapsulation resin composition is for use in wafer level packaging, panel level packaging, fan-out wafer level packaging, fan-out panel level packaging, or antenna-in-packaging.

<9>

A cured product of the encapsulation resin composition according to <1>.

<10>

A semiconductor device having the cured product of the encapsulation resin composition according to <9>.

The encapsulation resin composition of the present invention yields a reduced and restricted warpage even when applied to an electronic part requiring a low warpage property, and has a high relative permittivity and a low dielectric tangent. Thus, the present invention is useful as a material for encapsulating a semiconductor element-mounted surface of a substrate with a semiconductor element(s) mounted thereon or a semiconductor element-forming surface of a wafer with a semiconductor element(s) formed thereon.

### DETAILED DESCRIPTION OF THE INVENTION

The present invention is described in greater detail hereunder.

### [(A) Maleimide Compound Having at Least One Dimer Acid Frame-Derived Hydrocarbon Group Per Molecule]

An encapsulation resin composition of the present invention contains (A) a maleimide compound having at least one dimer acid frame-derived hydrocarbon group per molecule. A dimer acid refers to a liquid fatty acid of a dicarboxylic acid having 36 carbon atoms, which is obtained by dimerizing an unsaturated fatty acid having 18 carbon atoms and employing a vegetable fat or oil such as oleic acid and linoleic acid as its raw material. A dimer acid frame may contain multiple structures as opposed to one single type of frame, and there exist several types of isomers. Typical dimer acids are categorized under the names of (a) linear type, (b, c) monocyclic type, (d) aromatic ring type, and (e) polycyclic type.

In this specification, a dimer acid frame refers to a group induced from a dimer diamine having a structure established by substituting the carboxy groups in such dimer acid with primary aminomethyl groups. That is, as a dimer acid frame, it is preferred that the component (A) have a group obtained by substituting the two carboxy groups in any of the following dimer acids (a) to (e) with methylene groups. Further, as for the dimer acid frame-derived divalent hydrocarbon group in the component (A), more preferred from the perspectives of heat resistance and reliability of a cured product are those having a structure with a reduced number of carbon-carbon double bonds in the dimer acid frame-derived hydrocarbon group due to a hydrogenation reaction.

Here, in general, while a dimer acid may also contain a trimer (trimer acid) due to the fact that the raw material thereof is a natural substance such as a vegetable fat or oil, it is preferred that dimer acid-derived hydrocarbon groups are present at a high ratio, e.g., that dimer acid-derived hydrocarbon groups occupy 95% by mass or more of all the dimer acid- and trimer acid-derived hydrocarbon groups, because there will be achieved excellent dielectric properties, an excellent moldability as viscosity can now drop easily when heated, and even a tendency of being less susceptible to moisture absorption.

In this specification, a dimer acid (trimer acid) frame refers to a group derived from a dimer diamine (trimer triamine) having a structure established by substituting the carboxy group(s) in such dimer acid (trimer acid) with a primary aminomethyl group.

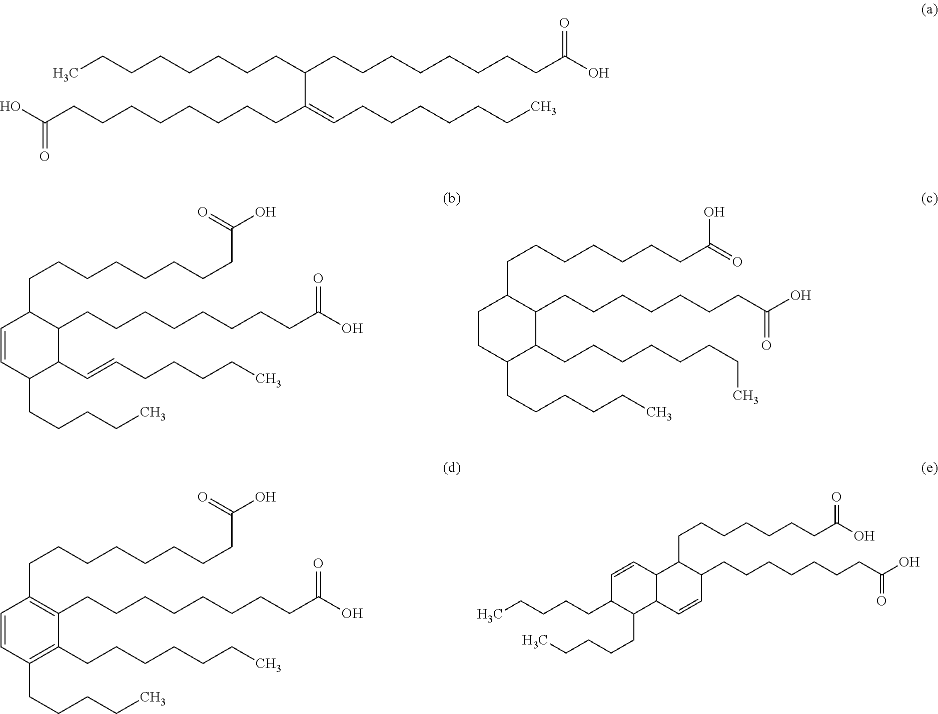 [SMILES: CCCCCCC/C=C(/CCCCCCCCC(=O)O)C(CCCCCCCC)CCCCCCCCC(=O)O ; CCCCC/C=C/C1C(CCCCC)C=CC(CCCCCCCCC(=O)O)C1CCCCCCCCC(=O)O ; CCCCCCCCC1C(CCCCCC)CCC(CCCCCCCC(=O)O)C1CCCCCCCC(=O)O ; CCCCCCCc1c(CCCCC)ccc(CCCCCCCCC(=O)O)c1CCCCCCCCC(=O)O ; CCCCCC1C=CC2C(C=CC(CCCCCCCC(=O)O)C2CCCCCCCC(=O)O)C1CCCCC]

The component (A) contained in the encapsulation resin composition of the present invention is preferably a maleimide compound represented by the following formula (1).

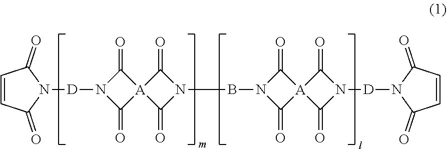

In the formula (1), A independently represents a tetravalent organic group having a cyclic structure; B independently represents a divalent hydrocarbon group that is not derived from a dimer acid frame and has 6 to 60 carbon atoms; D independently represents a divalent hydrocarbon group having 6 to 200 carbon atoms, in which at least one D represents a dimer acid frame-derived hydrocarbon group; m is 0 to 100, 1 is 0 to 200; no restrictions are imposed on an order of each repeating unit identified by m and 1, and a bonding pattern may be alternate, block or random.

A composition containing the maleimide compound represented by the formula (1) is superior to other compositions containing a general aromatic maleimide compound in dielectric properties; and is capable of reducing warpage of an encapsulated substrate due to a low elastic modulus after curing, and improving crack resistance in a reliability test.

In the formula (1), A independently represents a tetravalent organic group having a cyclic structure; particularly, it is preferred that A be any one of the tetravalent organic groups represented by the following structural formulae.

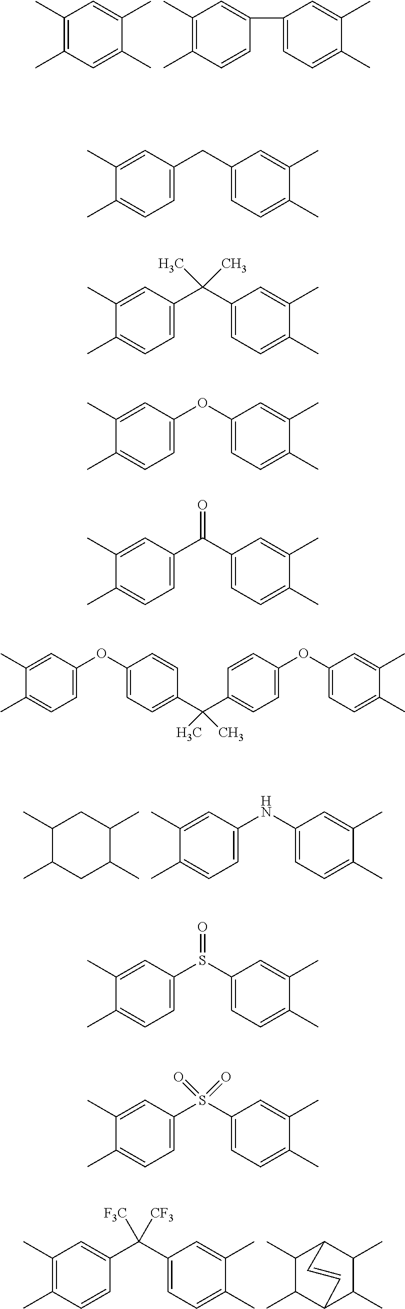

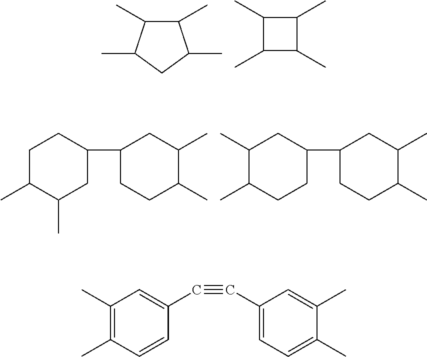

Bonds in the above structural formulae that are yet unbonded to substituent groups are to be bonded to carbonyl carbons forming cyclic imide structures in the formula (1).

In the formula (1), D independently represents a divalent hydrocarbon group having 6 to 200, preferably 8 to 100, more preferably 10 to 50 carbon atoms. Particularly, it is preferred that D be a branched divalent hydrocarbon group with at least one hydrogen atom in the above divalent hydrocarbon group being substituted by an alkyl or alkenyl group(s) having 6 to 200, preferably 8 to 100, more preferably 10 to 50 carbon atoms. The branched divalent hydrocarbon group may be either a saturated aliphatic hydrocarbon group or an unsaturated hydrocarbon group, and may also have an alicyclic structure or an aromatic ring structure in the midway of the molecular chain.

One specific example of the branched divalent hydrocarbon group may be a divalent hydrocarbon group derived from a dual-end diamine called dimer diamine. Thus, it is particularly preferred that D be a group obtained by substituting the two carboxy groups in any of the dimer acids represented by (a) to (e) with methylene groups, and there is at least one such dimer acid frame-derived hydrocarbon group in each molecule. At least one D represents a dimer acid frame-derived hydrocarbon group.

Further, in the formula (1), B independently represents a divalent hydrocarbon group that is not derived from a dimer acid frame and has 6 to 60 carbon atoms, preferably a divalent aliphatic hydrocarbon group, more preferably a divalent aliphatic hydrocarbon group having 6 to 30 carbon atoms. As such aliphatic hydrocarbon group, preferred is one having a cyclohexane frame. As a mode having such cyclohexane frame, there may be employed those having one cyclohexane ring, such as the one represented by the following formula (2); or those of polycyclic type with a plurality of cyclohexane rings being either bonded together via alkylene group(s) or bridged.

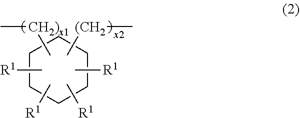

In the formula (2), R¹ independently represents a hydrogen atom or an alkyl group having 1 to 5 carbon atoms; each of x1 and x2 independently represents a number of 0 to 4.

Here, specific examples of R¹ include a hydrogen atom, a methyl group, an ethyl group, a n-propyl group, an isopropyl group, a n-butyl group, an isobutyl group, and a t-butyl group. Particularly, a hydrogen atom and a methyl group are preferred. Here, R's may be identical to or different from one another.

Further, each of x1 and x2 independently represents a number of 0 to 4, preferably a number of 0 to 2. Here, x1 and x2 may be identical to or different from each other.

Specific examples of B may include the divalent alicyclic hydrocarbon groups expressed by the following structural formulae.

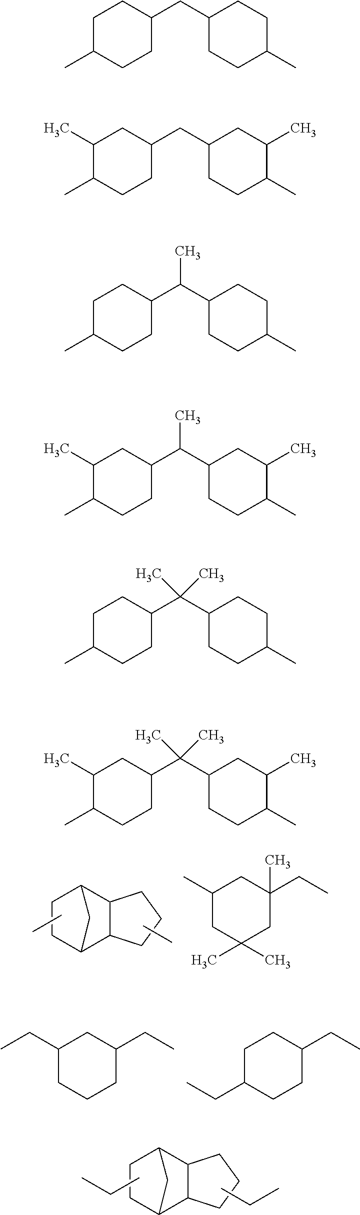

Bonds in the above structural formulae that are yet unbonded to substituent groups are to be bonded to nitrogen atoms forming cyclic imide structures in the formula (1).

In the formula (1), m is 0 to 100, preferably 1 to 60, more preferably 1 to 50; 1 is 0 to 200, preferably 0 to 50, more preferably 0 to 40. Extremely large m and I may lead to an impaired fluidity and a poor moldability accordingly.

No restrictions are imposed on the order of each repeating unit identified by m and l, and the bonding pattern may be alternate, block or random; a block bonding pattern is preferred in terms of ease in achieving a higher Tg.

In terms of handling property and achieving a small degree of warpage after encapsulation, the maleimide compound as the component (A) is preferably one being a solid at 25° C.

There are no particular restrictions on the number average molecular weight of the maleimide compound as the component (A); in terms of handling property of the composition, the number average molecular weight of this maleimide compound is preferably 800 to 50,000, more preferably 900 to 30,000. Further, other than the maleimide compound of the formula (1), the component (A) may contain another maleimide compound having at least one dimer acid frame-derived hydrocarbon group per molecule, and there may be employed one or more kinds of the component (A).

Here, the number average molecular weight mentioned in the present invention refers to a number average molecular weight that is measured by gel permeation chromatography (GPC) under the following conditions, using polystyrene as a reference substance.

[Measurement conditions]

Developing solvent: Tetrahydrofuran (THF)

Flow rate: 0.35 mL/min

Detector: Differential refractive index detector (RI)

Column: TSK Guardcolumn Super H-L

TSK gel Super HZ4000 (4.6 mm I.D.×15 cm×1)

TSK gel Super HZ3000 (4.6 mm I.D.×15 cm×1)

TSK gel Super HZ2000 (4.6 mm I.D.×15 cm×2)

(All manufactured by Tosoh Corporation)

Column temperature: 40° ° C.

Sample injection volume: 5 μL (THF solution with a concentration of 0.2% by mass)

In the composition of the present invention, the component (A) is preferably contained at a ratio of 5 to 60% by mass, more preferably 8 to 50% by mass, even more preferably 10 to 40% by mass, with the whole composition being regarded as 100% by mass.

### [(B) Reaction Initiator]

A reaction initiator used in the present invention is added to promote the cross-linking reaction of the component (A), or a reaction between the component (A) and a later-described heat-curable resin having reactive groups capable of reacting with maleimide groups. There are no particular restrictions on the component (B) so long as it is capable of promoting a curing reaction; a thermal radical polymerization initiator and/or an anionic polymerization initiator are preferred as the composition will exhibit a favorable curability.

As the thermal radical polymerization initiator, preferred are organic peroxides such as hydroperoxide, dialkyl peroxide, peroxyester, diacyl peroxide, peroxycarbonate, peroxyketal, and ketone peroxide. In terms of perseveration stability, more preferred is an organic peroxide having a 10-hour half-life temperature of 70 to 170° C. Specific examples of the thermal radical polymerization initiator include dicumyl peroxide, t-butyl peroxybenzoate, t-amyl peroxy benzoate, dibenzoyl peroxide, dilauroyl peroxide, 2,5-dimethyl-2,5-di(tert-butylperoxy)hexane, tert-butyl cumyl peroxide, di-tert-butyl peroxide, 1,1,3,3-tetramethylbutyl hydroperoxide, cumene hydroperoxide, and 1,1-di(t-butylperoxy)cyclohexane.

As the anionic polymerization initiator, preferred is at least one kind of compound selected from an imidazole compound, a phosphorus-based compound, an amine compound, and a urea-based compound.

Specific examples of the imidazole compound include imidazole, 2-methylimidazole, 2-ethylimidazole, 2-heptadecylimidazole, 1,2-dimethylimidazole, 2-ethyl-4-methylimidazole, 2-undecylimidazole, 2-phenylimidazole, 2-phenyl-4-methylimidazole, 1-benzyl-2-methylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 2-phenyl-4,5-dihydroxymethylimidazole, 2-phenyl-4-methyl-5-hydroxymethylimidazole, a diaminotriazine ring-containing imidazole such as 2,4-diamino-6-[2′-methylimidazolyl-(1′)]-ethyl-s-triazine, and microencapsulated products of these compounds.

Specific examples of the phosphorus-based compound include tributylphosphine, tri(p-methylphenyl)phosphine, tri(nonylphenyl)phosphine, triphenylphosphine, triphenylphosphine-triphenylborane, tetraphenylphosphine-tetraphenylborate, and microencapsulated products of these compounds.

Specific examples of the amine compound include triethylamine, benzyldimethylamine, α-methylbenzyldimethylamine, 1,8-diazabicyclo[5.4.0]undecene, tris(dimethylaminomethyl)phenol, and microencapsulated products of these compounds.

Specific examples of the urea-based compound include N,N,N′,N′-tetramethylurea, N′-phenyl-N, N-dimethylurea, N,N-diethylurea, N′-[3-[[[(dimethylamino)carbonyl]amino]methyl]-3,5,5-trimethylcyclohexyl]-N,N-dimethylurea, and N,N″-(4-methyl-1,3-phenylene)bis(N′,N′-dimethylurea).

Any one kind of these reaction initiators may be used alone, or two or more kinds of them may be used in combination. The reaction initiator is preferably added in an amount of 0.1 to 8 parts by mass, more preferably 0.2 to 6 parts by mass, even more preferably 0.3 to 4 parts by mass, per a total of 100 parts by mass of the component (A). The curing reaction will proceed in a sufficient manner when the reaction initiator is contained in an amount of not smaller than 0.1 parts by mass: the encapsulation resin composition will exhibit a favorable preservation stability when the reaction initiator is contained in an amount of not larger than 8 parts by mass.

[(C) High-Relative Permittivity Inorganic Filler Having Relative Permittivity of not Lower than 10 at 1 MHz]

A component (C) used in the present invention is added to increase the relative permittivity of a cured product of the encapsulation resin composition of the present invention, examples of which may include barium titanate, calcium titanate, strontium titanate, magnesium titanate, lead titanate, calcium zirconate, strontium zirconate, lanthanum oxide, and titanium oxide (excluding silica particles and alumina particles as a later-described component (D)). A perovskite-type composite oxide is preferred as the component (C) as a high relative permittivity can be achieved with the addition of a small amount thereof. Particularly, as the component (C), more preferred are calcium titanate, strontium titanate, calcium zirconate, and strontium zirconate, even more preferred are calcium titanate and strontium titanate, because when using these oxides, an increase in dielectric tangent can be suppressed while allowing relative permittivity to rise. Regardless of the types of these high-relative permittivity inorganic fillers, one kind of them may be used alone, or two or more kinds of them may be used in combination.

There are no particular restrictions on the shape of the component (C): the component (C) may, for example, have a spherical, an oval, a polyhedral, and an amorphous shape. The component (C) may also be one that has already been crushed. While there are no particular restrictions on an average particle size D50, the average particle size is preferably 0.1 to 20 μm, more preferably 0.15 to 10 μm, even more preferably 0.2 to 8 μm. Here, the average particle size D50 refers to a particle size corresponding to an integrated value of 50% in a volume particle size distribution measured by a laser diffraction/scattering measurement method.

The component (C) is preferably added in an amount of 10 to 500 parts by mass, more preferably 15 to 400 parts by mass, even more preferably 20 to 300 parts by mass, per the total of 100 parts by mass of the component (A).

Further, the component (C) is preferably contained in the composition at a ratio of 5 to 50% by mass, more preferably 8 to 48% by mass, even more preferably 10 to 45% by mass, with the whole composition being regarded as 100% by mass. When the component (C) is contained at a ratio of higher than 50% by mass, a poor moldability may be observed due to an impaired fluidity.

In order to improve a bond strength with the resin component, the component (C) may also be one that has already been surface-treated with a silane coupling agent. There may be listed an epoxy group-, an amino group-, a mercapto group-, a vinyl group-, a styryl group-, or a methacryl group-containing silane coupling agent, examples of which may include epoxysilanes such as 3-glycidoxypropyltrimethoxysilane, 3-glycidoxypropylmethyldiethoxysilane, and 2-(3,4-epoxycyclohexyl)ethyltrimethoxysilane: aminosilanes such as N-2-(aminoethyl)-3-aminopropyltrimethoxysilane, N-2-(aminoethyl)-8-aminooctyltrimethoxysilane, 3-aminopropyltrimethoxysilane, N-phenyl-3-aminopropyltrimethoxysilane, and 2,2-dimethoxy-1-phenyl-1-aza-2-silacyclopentane: mercaptosilanes such as 3-mercaptosilane and 3-episulfidoxypropyltrimethoxysilane: vinylsilanes such as vinyltrimethoxysilane and vinyltriethoxysilane: styrylsilanes such as p-styryltrimethoxysilane: and methacrylsilanes such as 3-methacryloxypropylmethyldimethoxysilane, 3-methacryloxypropyltrimethoxysilane, 3-methacryloxypropylmethyldiethoxysilane, and 3-methacryloxypropyltriethoxysilane. In terms of strength improvement, preferred are an amino group-, a methacryl group-, a vinyl group-, or a styryl group-containing silane coupling agent, particularly preferred is an amino group-containing silane coupling agent.

Any one kind of these silane coupling agents may be used alone, or two or more kinds of them may be used in combination.

Further, there are no particular restrictions on a treatment method using the silane coupling agent: a conventionally known method may be employed. The amount of the silane coupling agent used for surface treatment may be appropriately adjusted in accordance with desired properties: for example, the silane coupling agent may be used preferably in an amount of 0.1 to 5 parts by mass, more preferably 0.15 to 4 parts by mass, even more preferably 0.2 to 3 parts by mass, per 100 parts by mass of the component (C).

[(D) Silica Particles and/or Alumina Particles]

Silica particles and/or alumina particles (D) are added to lower the thermal expansion coefficient of the cured product of the encapsulation resin composition of the present invention, and improve the mechanical properties thereof: examples of such particles may include a spherical silica, molten silica, crystalline silica, cristobalite, and spherical alumina. As for the component (D), one kind thereof may be used alone, or two or more kinds thereof may be used in combination. The average particle size and shape of these silica particles and/or alumina particles can be selected depending on an intended use.

There are no particular restrictions on the maximum particle size of the component (D); the maximum particle size of the component (D) is preferably not larger than 55 μm, more preferably not larger than 40 μm, even more preferably not larger than 30 μm. Here, the maximum particle size refers to a maximum value obtained in a volume particle size distribution measurement carried out by a laser diffraction/scattering measurement method.

The average particle size D50 of the component (D) is preferably 0.1 to 30 μm, more preferably 0.15 to 25 μm, even more preferably 0.2 to 20 μm, in terms of a value obtained in a volume particle size distribution measurement carried out by a laser diffraction/scattering measurement method.

If necessary, the component (D) may be one that has been subjected to a top cut classification. The top cut classification here refers to a classification that is performed, via a wet sieving method, on the silica or alumina particles produced. The aperture of a sieve used in the classification is called a top cut diameter: the top cut diameter is a value at which a ratio of particles larger than such aperture is not higher than 2% by volume when measured by a volume particle size distribution measurement utilizing a laser diffraction/scattering measurement method. The top cut diameter is preferably 1 to 55 μm, more preferably 1.5 to 40 μm, even more preferably 2 to 30 μm, in a wet sieving method.

In order to improve a bond strength with the resin component, the component (D) may also be one that has already been surface-treated with a silane coupling agent. There may be listed an epoxy group-, an amino group-, a mercapto group-, a vinyl group-, a styryl group-, or a methacryl group-containing silane coupling agent, examples of which may include epoxysilanes such as 3-glycidoxypropyltrimethoxysilane, 3-glycidoxypropylmethyldiethoxysilane, and 2-(3,4-epoxycyclohexyl)ethyltrimethoxysilane: aminosilanes such as N-2-(aminoethyl)-3-aminopropyltrimethoxysilane, N-2-(aminoethyl)-8-aminooctyltrimethoxysilane, 3-aminopropyltrimethoxysilane, N-phenyl-3-aminopropyltrimethoxysilane, and 2,2-dimethoxy-1-phenyl-1-aza-2-silacyclopentane: mercaptosilanes such as 3-mercaptosilane and 3-episulfidoxypropyltrimethoxysilane; vinylsilanes such as vinyltrimethoxysilane and vinyltriethoxysilane: styrylsilanes such as p-styryltrimethoxysilane: and methacrylsilanes such as 3-methacryloxypropylmethyldimethoxysilane, 3-methacryloxypropyltrimethoxysilane, 3-methacryloxypropylmethyldiethoxysilane, and 3-methacryloxypropyltriethoxysilane. In terms of strength improvement, preferred are an amino group-, a methacryl group-, a vinyl group-, or a styryl group-containing silane coupling agent, particularly preferred is an amino group-containing silane coupling agent.

Any one kind of these silane coupling agents may be used alone, or two or more kinds of them may be used in combination.

Further, there are no particular restrictions on a treatment method using the silane coupling agent: a conventionally known method may be employed. The amount of the silane coupling agent used for surface treatment may be appropriately adjusted in accordance with desired properties: for example, the silane coupling agent may be used preferably in an amount of 0.1 to 5 parts by mass, more preferably 0.15 to 4 parts by mass, even more preferably 0.2 to 3 parts by mass, per 100 parts by mass of the component (D).

The component (D) is preferably added in an amount of 10 to 1,500 parts by mass, more preferably 20 to 1,100 parts by mass, even more preferably 30 to 900 parts by mass, per the total of 100 parts by mass of the component (A).

Further, the component (D) is preferably contained in the composition at a ratio of 5 to 90% by mass, more preferably 20 to 85% by mass, even more preferably 40 to 80% by mass, with the whole composition being regarded as 100% by mass.

A sum total of the components (C) and (D) is in an amount of 20 to 2,000 parts by mass, more preferably 30 to 1,500 parts by mass, even more preferably 40 to 1,200 parts by mass, per the total of 100 parts by mass of the component (A). Further, the components (C) and (D) are preferably contained in the composition at a ratio of 10 to 95% by mass, more preferably 50 to 90% by mass, even more preferably 60 to 85% by mass, with the whole composition being regarded as 100% by mass.

### <Other Additives>

The encapsulation resin composition of the present invention may further contain various additives as appropriate to the extent that the effects of the present invention are not impaired. These other additives are exemplified below.

[Heat-Curable Resin Having Reactive Group Capable of Reacting with Maleimide Group]

The present invention may further contain a heat-curable resin having reactive groups capable of reacting with maleimide groups.

No restrictions are imposed on the type of such heat-curable resin, examples of which may include various resins other than the component (A), such as an epoxy resin, a phenolic resin, a cyanate resin, a melamine resin, a silicone resin, a cyclic imide resin such as a maleimide compound other than the component (A), a urea resin, a heat-curable polyimide resin, a modified polyphenylene ether resin, a heat-curable acrylic resin, and an epoxy-silicone hybrid resin. Further, as a reactive group capable of reacting with maleimide groups, there may be listed, for example, an epoxy group, a maleimide group, a hydroxyl group, an acid anhydride group, an alkenyl group such as an allyl group and a vinyl group, a (meth)acryl group, and a thiol group. Here, as is the case with an epoxy group, the reactive group may for example be one generating an active species by reaction with imidazole, and undergoing anionic polymerization by reaction with maleimide groups. There are no particular restrictions on an added amount of the heat-curable resin having reactive groups capable of reacting with maleimide groups: such heat-curable resin may for example be in an amount of preferably 0 to 60% by mass, more preferably 0 to 50% by mass, even more preferably 0 to 40% by mass, in a sum total of heat-curable resin i.e. a sum total of the component (A) and the heat-curable resin having reactive groups capable of reacting with maleimide groups. Any one kind of these heat-curable resins may be used alone, or two or more kinds of them may be used in combination.

### [Flame Retardant]

The present invention may contain a flame retardant to impart a flame retardancy. Examples of such flame retardant include a halogenated epoxy resin, a phosphazene compound, a silicone compound, a zinc molybdate-supported talc, a zinc molybdate-supported zinc oxide, aluminum hydroxide, magnesium hydroxide, molybdenum oxide, and antimony trioxide. Any one kind of these flame retardants may be used alone, or two or more kinds of them may be used in combination; in terms of environmental load and securing fluidity, preferred are a phosphazene compound, a zinc molybdate-supported zinc oxide, molybdenum oxide, aluminum hydroxide, and magnesium hydroxide.

### [Ion-Trapping Agent]

The present invention may contain an ion-trapping agent to improve electric properties.

Examples of such ion-trapping agent include a hydrotalcite compound, a bismuth compound, and a zirconium compound: any one kind of these ion-trapping agents may be used alone, or two or more kinds of them may be used in combination.

### [Flexibility-Imparting Agent]

The present invention may contain a flexibility-imparting agent to impart a flexibility. Examples of such flexibility-imparting agent include silicone compounds such as a silicone oil, a silicone resin, a silicone-modified epoxy resin, and a silicone-modified phenolic resin; and thermoelastic elastomers such as a styrene resin and an acrylic resin. Any one kind of these flexibility-imparting agents may be used alone, or two or more kinds of them may be used in combination.

### [Colorant]

The present invention may contain a colorant to achieve a color stability of an appearance after encapsulation. Examples of such colorant include carbon black and titanium black: any one kind of these colorants may be used alone, or two or more kinds of them may be used in combination. Titanium black is preferred because a rise in dielectric tangent can be suppressed.

In addition to the above additives, the present invention may also contain an adhesion aid, a mold release agent, a reactive diluent, and a light stabilizer.

In terms of producing smaller packages, the relative permittivity (Dk) of the cured product of the encapsulation resin composition of the present invention at 10 GHz is preferably not lower than 4.0, more preferably not lower than 4.2, even more preferably not lower than 4.5.

In terms of reduction in transmission loss, the dielectric tangent (Df) of the cured product of the encapsulation resin composition of the present invention at 10 GHz is preferably not higher than 0.006, more preferably not higher than 0.005, even more preferably not higher than 0.004.

There are no particular restrictions on a method(s) for molding and measuring the cured product: for example, there may be employed a method where the encapsulation resin composition of the present invention is to be thermally cured with a vacuum press machine (by Nikko-Materials Co., Ltd.) to obtain a cured resin film having a size of 5 cm×5 cm and a thickness of 200 μm, followed by post-curing such cured resin film and then measuring the relative permittivity (Dk) and dielectric tangent (Df) thereof at the frequency of 10 GHz with a device in which a network analyzer (by Keysight Technologies) and a stripline (by KEYCOM Corporation) are connected.

### <Method for Producing Encapsulation Resin Composition>

As a method for producing the encapsulation resin composition of the present invention, there may be appropriately used a conventionally known method. The production method may for example be one employing a planetary mixer, a heated roll, a kneader, an extruder or the like. A heat-curable resin composition is obtained by melting and mixing given amounts of the components at a temperature of 60° C. or higher, and then cooling the mixture to a temperature of 30° C. or lower. If necessary, the heat-curable resin composition obtained may also be post-cured. It is preferred that post curing be performed at 150 to 250° ° C. for 0.5 to 5 hours. If the heat-curable resin composition obtained is a solid, the composition may be turned into the form of a powder by being crushed, turned into the form of tablets by tableting the crushed composition, turned into the form of granules by removing coarse grains and fine powders via a sieve after performing crushing, or turned into the form of a sheet using a pressing device or a T-die. Also, by applying to a support sheet a varnish with the encapsulation resin composition being dissolved in an organic solvent, and then by performing heating at a temperature of normally not lower than 80° C., preferably not lower than 100° C. for 1 to 60 min, the composition may be turned into the form of an uncured film from which the organic solvent has been removed. In terms of handling property at the time of use and reducing impacts of contamination caused by powdery dust, it is more preferred that the composition be in the form of granules, a sheet or a film.

### <Use of Encapsulation Resin Composition>

There are no particular restrictions on a use of the encapsulation resin composition of the present invention so long as it is used to encapsulate a semiconductor element-mounted surface of a substrate with a semiconductor element(s) mounted thereon or a semiconductor element-forming surface of a wafer with a semiconductor element(s) formed thereon: the composition of the present invention is effective as an encapsulation resin composition for use in wafer level packaging, panel level packaging, fan-out wafer level packaging, and fan-out panel level packaging. Further, the encapsulation resin composition of the present invention is also suitable for use in antenna-in-packaging as the composition exhibits low dielectric properties at high frequencies, and can be used to produce smaller packages as the composition has a high relative permittivity. There are no particular restrictions on a method for encapsulating a semiconductor device with the aid of the encapsulation resin composition of the present invention: while there may be used a conventional molding method such as transfer molding, injection molding, compression molding, cast molding, and lamination, more preferred are compression molding and lamination.

### Working Examples

The present invention is described in greater detail hereunder with reference to working and comparative examples; the present invention shall not be limited to the following working examples.

The components used in the working and comparative examples are shown below. (A) Maleimide compound having at least one dimer acid frame-derived hydrocarbon group per molecule

(A-1): Dimer acid frame-derived hydrocarbon group-containing bismaleimide compound represented by the following formula (SLK-3000 by Shin-Etsu Chemical Co., Ltd., number average molecular weight: 8,000)

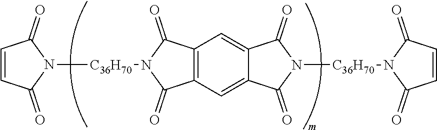

—C₃₆H₇₀— represents a dimer acid frame-derived structure.

m≈5 (Average value)

(A-2): Dimer acid frame-derived hydrocarbon group-containing bismaleimide compound represented by the following formula (SLK-2600 by Shin-Etsu Chemical Co., Ltd., number average molecular weight: 5,000)

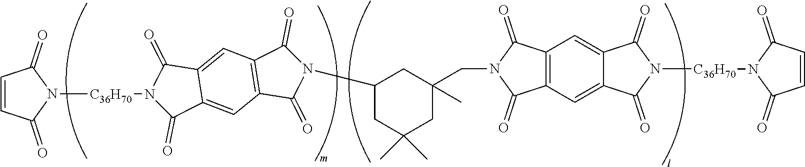

—C₃₆H₇₀— represents a dimer acid frame-derived structure.

m≈2, 1˜2 (Average value)

Maleimide compound for use in comparative example

(A′-3): Phenylmethane maleimide (BMI-2300 by Daiwakasei Industry Co., LTD.)

### (B) Reaction Initiator

(B-1): Dicumylperoxide (PERCUMYL D by NOF CORPORATION)

(B-2): 2-ethyl-4-methylimidazole (2E4MZ by SHIKOKU KASEI HOLDINGS CORPORATION)

(C) High-Relative Permittivity Inorganic Filler Having a Relative Permittivity of not Lower than 10 at 1 MHZ

(C-1): Calcium titanate (relative permittivity at 1 MHz: 140) (CT-03 by SAKAI CHEMICAL INDUSTRY CO., LTD.)

(C-2): Strontium titanate (relative permittivity at 1 MHz: 310) (ST-03 by SAKAI CHEMICAL INDUSTRY CO., LTD.)

(C-3): Barium titanate (relative permittivity at 1 MHz: 1,500) (BT-03 by SAKAI CHEMICAL INDUSTRY CO., LTD.)

### (D) Silica Particles or Alumina Particles

(D-1): Molten spherical silica having an average particle size of 4 μm and a top cut of 20 μm (relative permittivity at 1 MHz: 4.0) (MUF-4 by TATSUMORI LTD.)

(D-2): Silica prepared by performing dry surface treatment on 100 parts by mass of (D-1), using 0.3 parts by mass of N-phenyl-3-aminopropyltrimethoxysilane (KBM-573 by Shin-Etsu Chemical Co., Ltd.)

(D-3): Spherical alumina having an average particle size of 5 μm and a top cut of 25 μm (relative permittivity at 1 MHz: 8.9) (DAW-0525 by Denka Company Limited)

(D-4): Alumina prepared by performing dry surface treatment on 100 parts by mass of

(D-3): using 0.3 parts by mass of N-phenyl-3-aminopropyltrimethoxysilane (KBM-573 by Shin-Etsu Chemical Co., Ltd.)

### (E) Other Heat-Curable Resin

(E-1): Dicyclopentadiene-type epoxy resin (HP-7200 by DIC Corporation)

### [Working Examples 1 to 18; Comparative Examples 1 to 6]

The components were melted and mixed at a temperature of 80° C. and at the compounding ratios (parts by mass) shown in Tables 1 to 3, after which the mixture was cooled to 30° C. before being crushed. Next, a sieve having an aperture of 2 mm and a sieve having an aperture of 0.5 mm were used to remove coarse grains and fine powders, thereby obtaining a granular resin composition. Each composition was evaluated in accordance with the methods shown below, and the results thereof are shown in Tables 1 to 3.

### <Warpage>

A compression molding device (by APIC YAMADA CORPORATION) was used to mold the above resin composition on a 12-inch silicon wafer having a thickness of 775 μm so that a resin thickness after molding would be 400 μm. Molding temperatures and molding times are shown in Tables 1 to 3. After performing post curing at 180° C. for two hours, warpage of such wafer was measured by a shadow moire-type warpage measurement device (by Akrometrix).

### <Dielectric Properties>

A vacuum press machine (by Nikko-Materials Co., Ltd.) was used to thermally cure the resin composition at the molding temperatures shown in Tables 1 to 3 and for the molding times shown in these tables to obtain a cured resin film of 5 cm×5 cm×200 μm t. After post-curing this cured resin film at 180ºC for two hours, a network analyzer (by Keysight Technologies) and a stripline (by KEYCOM Corporation) were connected to measure the relative permittivity (Dk) and dielectric tangent (Df) of the post-cured film at a frequency of 10 GHz.

TABLE 1

| | | | Working example | | | | | | | | |
|---|---|---|---|---|---|---|---|---|---|---|---|
| Composition table (part by mass) | | | 1 | 2 | 3 | 4 | 5 | 6 | 7 | 9 | 10 |
| (A) | A-1 | SLK-3000 | 100 | 100 | 100 | 100 | 100 | 100 | 100 | 100 | 100 |
| | A-2 | SLK-2600 | | | | | | | | | |
| | A′-3 | BMI-2300 | | | | | | | | | |
| (B) | B-1 | PERCUMYL D | 2 | 2 | 2 | 2 | 2 | 2 | 2 | 2 | 2 |
| | B-2 | 2E4MZ | | | | | | | | | |
| (C) | C-1 | CT-03 | 32 | 32 | | | 67 | 67 | | 84 | 97 |
| | C-2 | ST-03 | | | 32 | | | | 67 | | |
| | C-3 | BT-03 | | | | 32 | | | | | |
| (D) | D-1 | MUF-4 | 127 | | | | | | | | |
| | D-2 | MUF-4 (treated | | 127 | 127 | 127 | | | | | |
| | | with KBM-573) | | | | | | | | | |
| | D-3 | DAW-0525 | | | | | 207 | | | | |
| | D-4 | DAW-0525 | | | | | | 207 | 207 | 350 | 461 |
| | | (treated with | | | | | | | | | |
| | | KBM-573) | | | | | | | | | |
| (E) | E-1 | HP-7200 | | | | | | | | | |
| Contained | (C) | | 12 | 12 | 12 | 12 | 18 | 18 | 18 | 16 | 15 |
| amount | (D) | | 49 | 49 | 49 | 49 | 55 | 55 | 55 | 65 | 70 |
| (wt %) | (C) + (D) | | 61 | 61 | 61 | 61 | 73 | 73 | 73 | 81 | 85 |
| Property | Molding temperature (° C.) | | 150 | 150 | 150 | 150 | 150 | 150 | 150 | 150 | 150 |
| evaluation | Molding time (sec.) | | 600 | 600 | 600 | 600 | 600 | 600 | 600 | 600 | 600 |
| | Warpage (mm) | | 0.20 | 0.15 | 0.16 | 0.16 | 0.42 | 0.40 | 0.41 | 0.60 | 0.73 |
| | Dielectric | Dk | 4.2 | 4.2 | 4.2 | 4.2 | 5.6 | 5.6 | 5.4 | 6.2 | 6.7 |
| | property | | | | | | | | | | |
| | (10 GHz) | Df | 0.0013 | 0.0011 | 0.0010 | 0.0050 | 0.0023 | 0.0023 | 0.0022 | 0.0024 | 0.0027 |

TABLE 2

| | | | Working example | | | | | | | |
|---|---|---|---|---|---|---|---|---|---|---|
| Composition table (part by mass) | | | 11 | 12 | 13 | 14 | 15 | 16 | 17 | 18 |
| (A) | A-1 | SLK-3000 | 100 | | 70 | 50 | 100 | 100 | 100 | 100 |
| | A-2 | SLK-2600 | | 100 | 30 | 50 | | | | |
| | A′-3 | BMI-2300 | | | | | | | | |
| (B) | B-1 | PERCUMYL D | | 2 | 2 | 2 | 2 | 2 | 2 | 2 |
| | B-2 | 2E4MZ | 2.1 | | | | | | | |
| (C) | C-1 | CT-03 | 67 | 67 | 67 | 67 | 101 | 134 | 165 | 67 |
| | C-2 | ST-03 | | | | | | | | |
| | C-3 | BT-03 | | | | | | | | |
| (D) | D-1 | MUF-4 | | | | | | | | |
| | D-2 | MUF-4 | | | | | | | | 83 |
| | | (treated with KBM-573) | | | | | | | | |
| | D-3 | DAW-0525 | | | | | | | | |
| | D-4 | DAW-0525 | 207 | 207 | 207 | 207 | 175 | 143 | 114 | 124 |
| | | (treated with KBM-573) | | | | | | | | |
| (E) | E-1 | HP-7200 | 5.3 | | | | | | | |
| Contained | (C) | | 18 | 18 | 18 | 18 | 27 | 35 | 43 | 18 |
| amount | (D) | | 54 | 55 | 55 | 55 | 46 | 38 | 30 | 55 |
| (wt %) | (C) + (D) | | 72 | 73 | 73 | 73 | 73 | 73 | 73 | 73 |
| Property | Molding temperature (° C.) | | 160 | 150 | 150 | 150 | 150 | 150 | 150 | 150 |
| evaluation | Molding time (sec.) | | 600 | 600 | 600 | 600 | 600 | 600 | 600 | 600 |
| | Warpage (mm) | | 0.42 | 0.78 | 0.50 | 0.60 | 0.45 | 0.47 | 0.52 | 0.35 |
| | Dielectric | Dk | 5.8 | 5.6 | 5.6 | 5.6 | 6.7 | 7.7 | 8.1 | 5.1 |
| | property | Df | 0.0028 | 0.0034 | 0.0025 | 0.0029 | 0.0022 | 0.0021 | 0.0020 | 0.0020 |
| | (10 GHz) | | | | | | | | | |

TABLE 3

| | | | Comparative example | | | | | |
|---|---|---|---|---|---|---|---|---|
| Composition table (part by mass) | | | 1 | 2 | 3 | 4 | 5 | 6 |
| (A) | A-1 | SLK-3000 | | 100 | | 50 | 100 | 100 |
| | A-2 | SLK-2600 | | | 100 | 50 | | |
| | A′-3 | BMI-2300 | 100 | | | | | |
| (B) | B-1 | PERCUMYL D | 2 | 2 | 2 | 2 | 2 | 2 |
| | B-2 | 2E4MZ | | | | | | |
| (C) | C-1 | CT-03 | 67 | | | | | |
| | C-2 | ST-03 | | | | | | |
| | C-3 | BT-03 | | | | | | |
| (D) | D-1 | MUF-4 | | | | | 270 | |
| | D-2 | MUF-4 | | | | | | |
| | | (treated with KBM-573) | | | | | | |
| | D-3 | DAW-0525 | | | | | | |
| | D-4 | DAW-0525 | 207 | 207 | 207 | 207 | | 270 |
| | | (treated with KBM-573) | | | | | | |
| (E) | E-1 | HP-7200 | | | | | | |
| Contained | (C) | | 18 | 0 | 0 | 0 | 0 | 0 |
| amount | (D) | | 55 | 67 | 67 | 67 | 73 | 73 |
| (wt %) | (C) + (D) | | 73 | 67 | 67 | 67 | 73 | 73 |
| Property | Molding temperature (° C.) | | 170 | 150 | 150 | 150 | 150 | 150 |
| evaluation | Molding time (sec.) | | 600 | 600 | 600 | 600 | 600 | 600 |
| | Warpage (mm) | | 4.2 | 0.25 | 0.71 | 0.52 | 0.29 | 0.35 |
| | Dielectric | Dk | 6.0 | 3.6 | 3.6 | 3.6 | 3.2 | 3.7 |
| | property | Df | 0.0110 | 0.0028 | 0.0030 | 0.0026 | 0.0011 | 0.0021 |
| | (10 GHz) | | | | | | | |

As shown in Tables 1 to 3, the resin composition of the present invention exhibited a reduced and restricted warpage after molding, and has a high relative permittivity and a low dielectric tangent. Thus, the encapsulation resin composition of the present invention is suitable for encapsulating a semiconductor element-mounted surface of a substrate with a semiconductor element(s) mounted thereon or a semiconductor element-forming surface of a wafer with a semiconductor element(s) formed thereon.

What is claimed is:

1. An encapsulation resin composition for encapsulating a semiconductor element-mounted surface of a substrate with one or more semiconductor elements mounted thereon or a semiconductor element-forming surface of a wafer with one or more semiconductor elements formed thereon, comprising:
(A) a maleimide compound having at least one dimer acid frame-derived hydrocarbon group per molecule;
(B) a reaction initiator;
(C) a high-relative permittivity inorganic filler having a relative permittivity of not lower than 10 at 1 MHz, the inorganic filler (C) being an inorganic filler other than the following component (D); and
(D) silica particles and/or alumina particles.

2. The encapsulation resin composition according to claim 1, wherein the component (A) is a maleimide compound represented by the following formula (1) 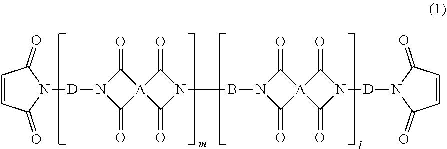
wherein A independently represents a tetravalent organic group having a cyclic structure; B independently represents a divalent hydrocarbon group that is not derived from a dimer acid frame and has 6 to 60 carbon atoms; D independently represents a divalent hydrocarbon group having 6 to 200 carbon atoms, in which at least one D represents a dimer acid frame-derived hydrocarbon group; m is 0 to 100, 1 is 0 to 200; no restrictions are imposed on an order of each repeating unit identified by m and 1, and a bonding pattern may be alternate, block or random.

3. The encapsulation resin composition according to claim 2, wherein A in the formula (1) is any one of the tetravalent organic groups represented by the following structural formulae 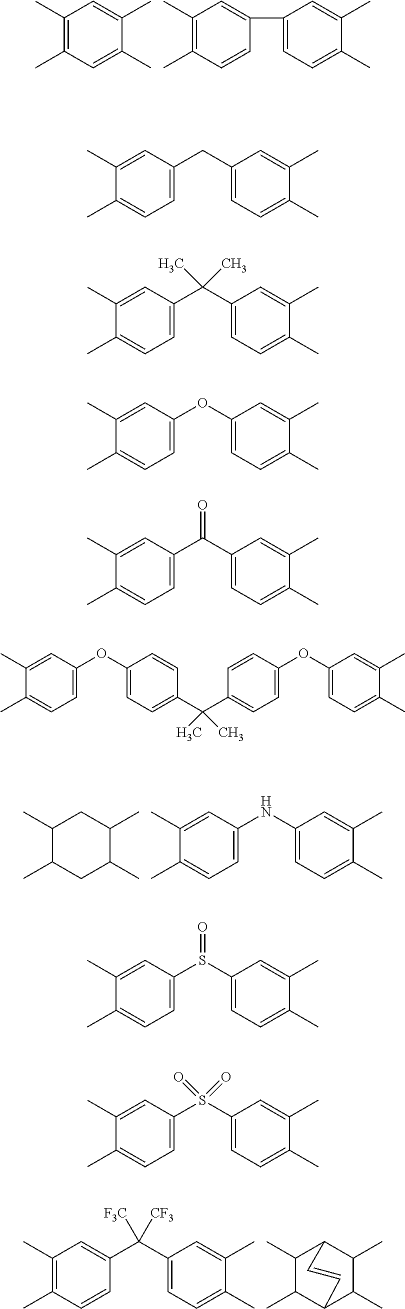 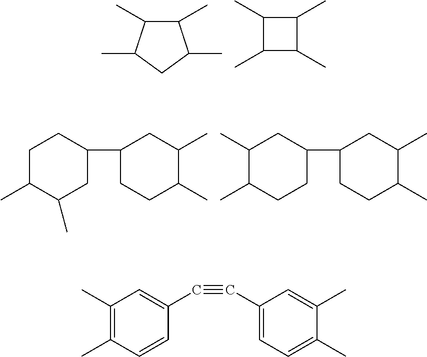
wherein bonds that are yet unbonded to substituent groups are to be bonded to carbonyl carbons forming cyclic imide structures in the formula (1).

4. The encapsulation resin composition according to claim 1, wherein the component (C) is at least one kind selected from the group consisting of barium titanate, calcium titanate, strontium titanate, magnesium titanate, lead titanate, calcium zirconate, strontium zirconate, lanthanum oxide, and titanium oxide.

5. The encapsulation resin composition according to claim 1, wherein the component (C) is contained in an amount of 5 to 50% by mass with respect to the whole composition, the component (D) is contained in an amount of 5 to 90% by mass with respect to the whole composition, and a sum total of the components (C) and (D) is in an amount of 10 to 95% by mass with respect to the whole composition.

6. The encapsulation resin composition according to claim 1, wherein the component (B) is a thermal radical polymerization initiator and/or an anionic polymerization initiator.

7. The encapsulation resin composition according to claim 1, wherein the encapsulation resin composition is in the form of granules, a sheet or a film.

8. The encapsulation resin composition according to claim 1, wherein the encapsulation resin composition is for use in wafer level packaging, panel level packaging, fan-out wafer level packaging, fan-out panel level packaging, or antenna-in-packaging.

9. A cured product of the encapsulation resin composition according to claim 1.

10. A semiconductor device having the cured product of the encapsulation resin composition according to claim 9.
